(19) United States
(12) Patent Application Publication
(10) Pub. No.: US 2004/0219753 A1
(43) Pub. Date: Nov. 4, 2004

(54) Method of manufacturing semiconductor device

(75) Inventor: Takio Ohno, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/690,707

(22) Filed: Oct. 23, 2003

(30) Foreign Application Priority Data
May 1, 2003 (JP) 2003-126148(P)

(51) Int. Cl. H01L 21/8234; H01L 21/8238; H01L 21/336

(52) U.S. Cl. 438/275; 438/231; 438/287; 438/258

(57) ABSTRACT

A method of manufacturing a semiconductor device includes the steps of: forming first and second active areas at a main surface of a silicon substrate; forming a first thermal oxide film on the main surface of the silicon substrate; selectively removing a prescribed portion of the first thermal oxide film to expose the second active area; forming a second thermal oxide film on the first and second active areas; performing an annealing process on the first and second thermal oxide films at or above a temperature for forming the second thermal oxide film; and forming first and second gate electrodes on the first and second active areas such that the first and second thermal oxide films undergoing the annealing process lie between them. Consequently, a method of manufacturing a semiconductor device wherein residual stress inside a semiconductor substrate is reduced is provided.

### BACKGROUND OF THE INVENTION

1. Field of the Invention

The present invention relates to a method of manufacturing a semiconductor device. More particularly, the present invention relates to a method of manufacturing a semiconductor device having a dual gate insulating film structure.

2. Description of the Background Art

In recent years, a semiconductor device where field effect transistors having gate insulating films of different thicknesses are provided on a single semiconductor substrate has increasingly been produced. This structure, which is generally called a dual gate insulating film structure, is suitable for mounting field effect transistors with different driving voltages on a single semiconductor substrate.

A method of manufacturing a semiconductor device having the dual gate insulating film structure is disclosed in Japanese Patent Laying-Open Nos. 2000-243856 and 2002-246480.

Among them, the method of manufacturing a semiconductor device having the dual gate insulating film structure disclosed in Japanese Patent Laying-Open No. 2000-243856 includes the steps of: forming a first dielectric layer on first and second active areas; removing a portion of the first dielectric layer using a patterned resist film to expose the second active area; and removing the resist film to subsequently form a second dielectric layer on the second active area.

The method of manufacturing a semiconductor device having the dual gate insulating film structure disclosed in Japanese Patent Laying-Open No. 2002-246480 includes the steps of: depositing a nitride film and a chemical vapor deposition (CVD) oxide film successively on first and second active areas; exposing a surface of a semiconductor substrate in the second active area using as a mask the CVD oxide film patterned through a photolithography process; selectively forming a first thermal oxide film at the exposed surface only; and exposing a surface of the semiconductor substrate in the first active area to form a second thermal oxide film at the exposed surface.

As a semiconductor device has been miniaturized in recent years, a shallow trench isolation (STI) structure serving for device isolation has increasingly been adopted. When the STI structure is adopted for device isolation, in a step of forming a gate insulating film after forming a trench isolation film, sidewalls of the trench isolation film inside a semiconductor substrate are oxidized to cause volume expansion. As a result, residual internal stress in the semiconductor substrate tends to increase. Additionally, as an active area is miniaturized, internal local stress of a semiconductor substrate disadvantageously becomes noticeable. Still additionally, since a gate insulating film is made thinner as a semiconductor device is miniaturized, a low-temperature process is required for accurately forming the gate insulating film. Consequently, an annealing effect, i.e., an effect of mitigating internal stress, which is otherwise obtained from a step of forming the gate insulating film, is weakened. Accordingly, the internal stress in a semiconductor substrate tends to be greater than before.

Such internal stress induces a crystal defect inside a semiconductor substrate, and causes an increase in junction leakage and leakage current between the source and the drain of a transistor. Therefore, it causes a decrease in yield and reliability. Crystal distortion caused by such internal stress also tends to decrease electron mobility, disadvantageously resulting in a decrease in driving ability especially in a transistor with a narrower active area.

Additionally, when the gate insulating film is formed through a low-temperature process, its quality is disadvantageously degraded. Degradation of the film quality also causes a decrease in yield and reliability. Still additionally, the internal stress described above can further degrade quality of a trench isolation film at and near its ends significantly, resulting in increase in leakage current and dielectric breakdown in a transistor. Disadvantageously, this causes a further decrease in yield and reliability.

### SUMMARY OF THE INVENTION

An object of the present invention is to provide a method of manufacturing a semiconductor device having a dual gate insulating structure, by which reduction of residual stress inside a semiconductor substrate as well as improvement of the quality of a gate insulating film can be achieved.

In order to achieve the object described above, a method of manufacturing a semiconductor device according to the present invention is a method of manufacturing a semiconductor device where field effect transistors with gate insulating films of different thicknesses are provided. The method includes the steps of:

(a) forming a trench isolation film at a main surface of a semiconductor substrate to form first and second active areas;

(b) forming a first insulating film on the main surface of the semiconductor substrate to cover the first and second active areas;

(c) selectively removing a prescribed portion of the first insulating film to expose the second active area;

(d) forming a second insulating film on the first active area and the second active area;

(e) performing an annealing process on the first and second insulating films at or above a temperature for forming the second insulating film; and

(f) forming a first gate electrode on the first active area such that the first and second insulating films undergoing the annealing process lie between the first active area and the first gate electrode, and forming a second gate electrode on the second active area such that the second insulating film undergoing the annealing process lies between the second active area and the second gate electrode.

Thus, the residual stress generated inside a semiconductor substrate can remarkably be reduced and the quality of the gate insulating film can be improved in manufacturing a semiconductor device with a dual gate insulating film structure. Consequently, a semiconductor device of higher performance and reliability can be manufactured with improved yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 6 are cross sectional views schematically showing first to sixth steps of a method of manufacturing a semiconductor device in an embodiment of the present invention.

### DESCRIPTION OF THE PREFERRED EMBODIMENT

For a method of manufacturing a semiconductor device in an embodiment of the present invention, manufacturing steps will be described in detail one by one with reference to the drawings. It is noted that the method of manufacturing a semiconductor device in the present embodiment will illustrate a case where field effect transistors are formed in array at a main surface of a semiconductor substrate.

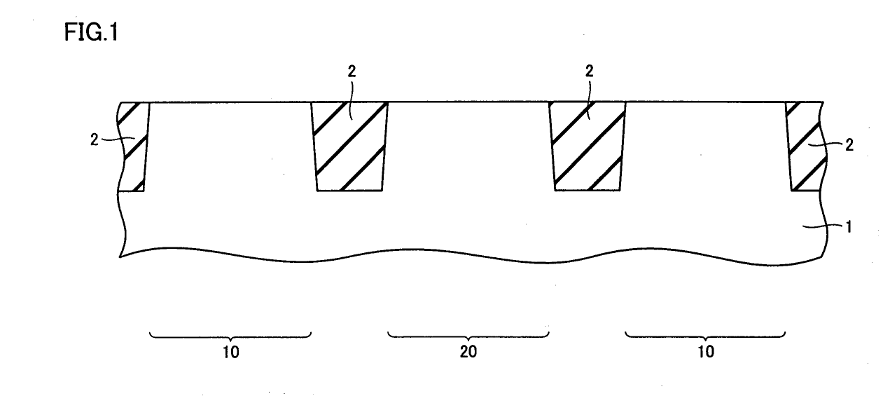

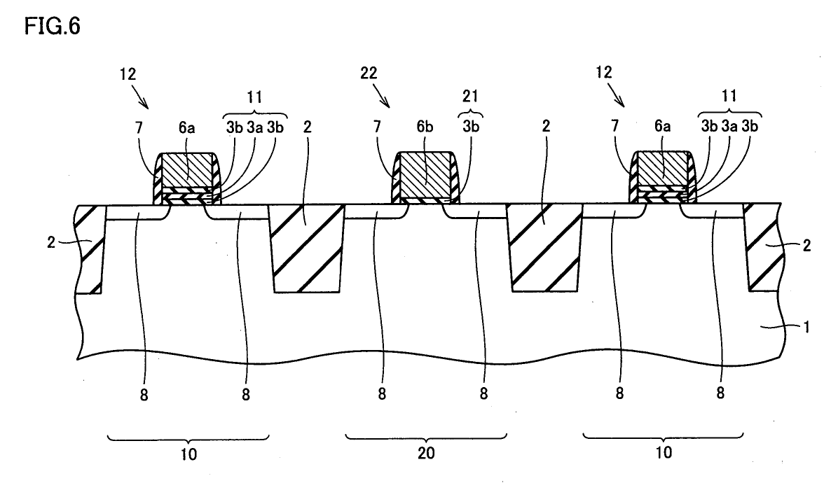

As shown in FIG. 1, in a first step, a trench isolation film 2 is formed at a semiconductor substrate or a silicon substrate 1 to form a first active area 10 and a second active area 20. First active area 10 is an area where a first field effect transistor 12 with a gate oxide film of relatively large thickness (see FIG. 6) is formed in a subsequent step. Second active area 20 is an area where a field effect transistor 22 with a gate oxide film of relatively small thickness (see FIG. 6) is formed in a subsequent step.

A manufacturing method usually employed for an STI structure can be adopted in the first step. More particularly, a pad oxide film is firstly formed directly on a main surface of silicon substrate 1. A polysilicon layer and a silicon nitride film are successively deposited on the pad oxide film to form a multi-layer film of three layers including the pad oxide film, the polysilicon layer, and the silicon nitride film (not shown). A resist film patterned to a desired form using a photolithography technique (not shown) is then formed on the silicon nitride film. The multi-layer film of three layers described above is partially etched using the resist film as a mask to selectively expose an area of the main surface of silicon substrate 1 where trench isolation film 2 is to be formed. The resist film is then removed.

Silicon substrate 1 is then dry-etched using as a mask the silicon nitride film, which lies as an uppermost layer of the multi-layer film of three layers remaining on the main surface of silicon substrate 1 as described above, to form a trench at the main surface of silicon substrate 1. After the sidewalls of the trench formed as such are oxidized, a silicon oxide film is deposited in the trench using the CVD method to fill it. After an planarization process using the chemical mechanical polishing (CMP), the multi-layer of three layers remaining on silicon substrate 1 is removed to form trench isolation film 2 as shown in FIG. 1. Trench isolation film 2 separates silicon substrate 1 into first active area 10 and second active area 20.

If an usually employed complementary metal oxide semiconductor (CMOS) process is adopted, an ion-implanting step, i.e., a step of forming p-well and n-well regions, is added after the step of forming trench isolation film 2.

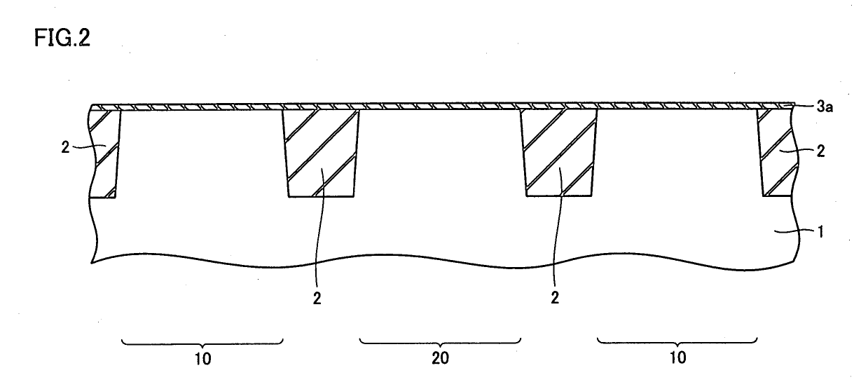

As shown in FIG. 2, in a second step, a first thermal oxide film 3a is then formed as a first insulating film on first active area 10 and second active area 20. First thermal oxide film 3a is formed by a heat treatment of silicon substrate 1 shown in FIG. 1 in an atmosphere of oxygen. The thermal oxidization process is implemented by a heat treatment using a furnace or a heat treatment using a lamp system called RTA. Typically, first thermal oxide film 3a formed in the step is approximately 20 nm or less in thickness. Though the thermal oxidization process described above is typically performed at a temperature approximately between 700° C. and 1100° C., a low-temperature process is demanded as a semiconductor device has been miniaturized in recent years. Therefore, the process is preferably performed at a temperature approximately between 700° C. and 1000° C.

If the thermal oxidization process is performed by a wet process, a mixed gas including oxygen and water vapor is used as an atmosphere. If the thermal oxidization process is performed by a dry process, oxygen is used as an atmosphere. It is noted that a wet process is preferably adopted to suppress undesirable oxidization at an interface between trench isolation film 2 and silicon substrate 1 (especially at the sidewalls of trench isolation film 2). Accordingly, residual internal stress in silicon substrate 1 can be reduced to a relatively smaller level.

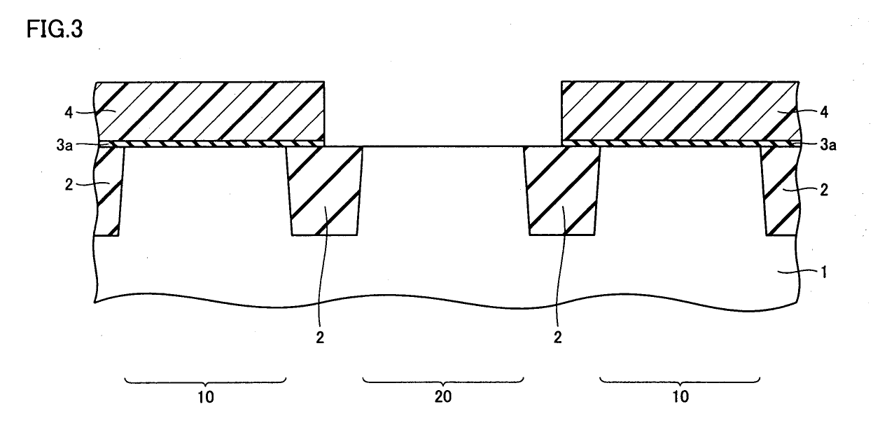

As shown in FIG. 3, in a third step, a prescribed portion of first thermal oxide film 3a described above is then selectively removed to expose second active area 20. A particular method of exposing second active area 20 includes the steps of, for example, forming a patterned resist film 4 on first thermal oxide film 3a, and etching away first thermal oxide film 3a placed on second active area 20 using resist film 4 as a mask. It is noted that, after the etching process completed, resist film 4 which is now unnecessary is removed.

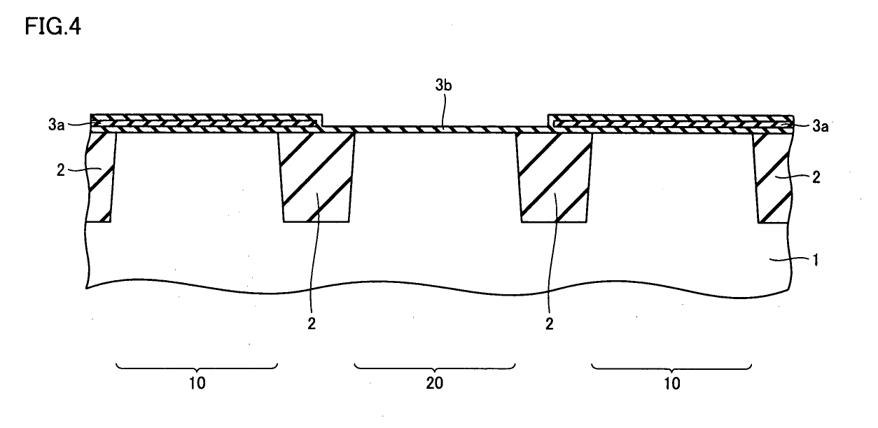

As shown in FIG. 4, in a fourth step, a second thermal oxide film 3b is then formed as a second insulating film on first active area 10 and second active area 20. Second thermal oxide film 3b is formed by removing resist film 4 from silicon substrate 1 shown in FIG. 3 to perform a heat treatment on the silicon substrate in an atmosphere of oxygen. As in the step of forming first thermal oxide film 3a, the thermal oxidization process is implemented by a heat treatment using a furnace or a heat treatment using a lamp system called RTA. Typically, second thermal oxide film 3b formed in the step is approximately 20 nm thick or less, and more preferably 5 nm thick or less. Since second thermal oxide film 3b is formed to be 5 nm thick or less as such, a thin gate film accommodating a miniaturized semiconductor device in recent years can be formed.

Though the thermal oxidization process described above is typically performed at a temperature approximately between 700° C. and 1100° C., it is more preferably performed at a temperature approximately between 700° C. and 1000° C. Since second thermal oxide film 3b is formed at 1000° C. or below as such, a low-temperature process which has been adopted with the recent miniaturization of a semiconductor device can be accommodated. Additionally, an effect obtained from an annealing process to mitigate the stress as described below, will remarkably be exhibited.

As in the step of forming first thermal oxide film 3a described above, if the thermal oxidization process is performed by a wet process, a mixed gas including oxygen and water vapor is adopted as an atmosphere. If the thermal oxidization process is performed by a dry process, oxygen is adopted as an atmosphere. It is noted that a wet process is preferably adopted to suppress undesirable oxidization at an interface between trench isolation film 2 and silicon substrate 1 (especially at the sidewalls of trench isolation film 2). Accordingly, residual internal stress in silicon substrate 1 can be reduced to a relatively smaller level.

In the third step described above, it is noted that second thermal oxide film 3b grows, extending continuously in upward and downward directions from first thermal oxide film 3a formed in advance on first active area 10. In other words, a multi-layer thermal oxide film including first thermal oxide film 3a and second thermal oxide film 3b is formed on first active area 10. In contrast, second thermal oxide film 3b formed on second active area 20 is a film newly formed at the main surface of silicon substrate 1. As a result, a mono-layer thermal oxide film including second thermal oxide film 3b only is formed on second active area 20.

In the third step described above, a silicon oxinitride film may be used as the second insulating film in place of second thermal oxide film 3b. In this case, the silicon oxinitride film is formed by performing a thermal nitriding process on silicon substrate 1 described above in an atmosphere of nitrous oxide. In this case, the thermal nitriding process is typically performed at a temperature approximately between 900° C. and 1000° C. For another thermal nitriding method of forming the silicon oxinitride film, a thermal nitriding process in an atmosphere of ammonia, nitrogen monoxide or the like, can be adopted.

According to the method of manufacturing a semiconductor device in this embodiment, an annealing process is performed after the step of forming second thermal oxide film 3b in order to mitigate residual internal stress in silicon substrate 1 and improve the quality of first thermal oxide film 3a and second thermal oxide film 3b. The annealing process is performed at or above a temperature for forming second thermal oxide film 3b. For example, if second thermal oxide film 3b is formed at 900° C., a temperature for the annealing process is determined to be at least 900° C.

More preferably, the annealing process is performed with a RTA method. The annealing process using the RTA method takes shorter time than an annealing process using a furnace. Consequently, re-diffusion of impurities implanted into silicon substrate 1 prior to the annealing process can be controlled with higher accuracy. This means that the annealing process using the RTA method can effectively suppress a short channel effect generated as a semiconductor device is miniaturized.

If the annealing process described above is performed with the RTA, it is preferably performed in an atmosphere of inert gas such as nitrogen gas, argon gas, or the like. By using inert gas as such, re-oxidization of silicon substrate 1 can be prevented.

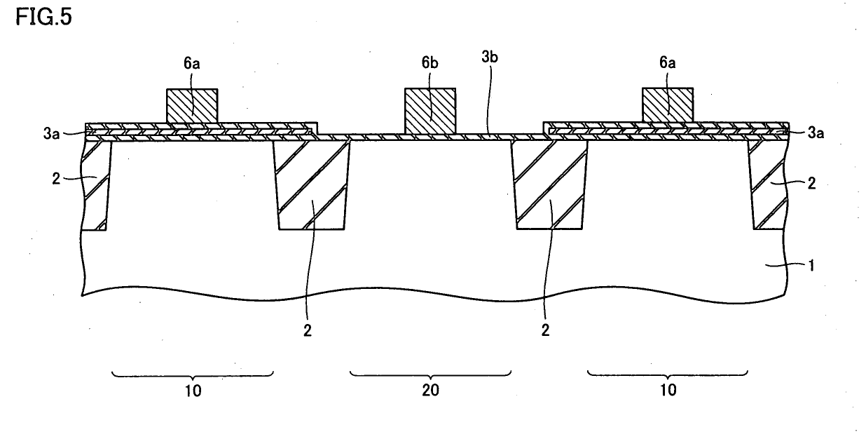

As shown in FIG. 5, in a fifth step, a first gate electrode 6a is then formed on first active area 10 such that first and second thermal oxide films 3a, 3b undergoing the annealing process lie between first active area 10 and first gate electrode 6a, and a second gate electrode 6b is formed on second active area 20 such that second thermal oxide film 3b undergoing the annealing process lies between second active area 20 and second gate electrode 6b. More specifically, a polysilicon layer 6 is formed on second thermal oxide film 3b using a CVD method to form a patterned resist film on polysilicon layer 6. Polysilicon layer 6 is then partially etched using the resist film as a mask to form gate electrodes 6a, 6b.

As shown in FIG. 6, in a sixth step, impurities are then implanted into first and second active areas 10, 20 to form source/drain regions 8. First and second thermal oxide films 3a, 3b are then removed from silicon substrate 1, excluding a portion of first and second thermal oxide films 3a, 3b positioned immediately below gate electrode 6a and a portion of first thermal oxide film 3b positioned immediately below gate electrode 6b. A sidewall insulating film 7 is then formed on each sidewall of gate electrodes 6a, 6b to form first and second field effect transistors 12, 22. Through these steps described above, the semiconductor device where field effect transistors with gate insulating films of different thicknesses are provided as shown in FIG. 6 is manufactured.

In the semiconductor device manufactured by the above-described method, as shown in FIG. 6, first field effect transistor 12 formed at first active area 10 has a multi-layer first gate oxide film 11 including first thermal oxide film 3a and second thermal oxide film 3b while second field effect transistor 22 formed at second active area 20 has a mono-layer second gate oxide film 21 including only the second thermal oxide film 3b. In other words, first field effect transistor 12 has a gate insulating film larger in thickness by thickness of first thermal oxide film 3a as compared with second field effect transistor 22. As a result, first field effect transistor 12 requires a larger gate driving voltage than second field effect transistor 22.

The characteristic steps in the method of manufacturing a semiconductor device in the present embodiment as described above can be summarized as follows: the method of manufacturing a semiconductor device includes the steps of: (a) forming trench isolation film 2 at a main surface of silicon substrate 1 serving as a semiconductor substrate to form first and second active areas 10, 20; (b) forming first thermal oxide film 3a as a first insulating film on the main surface of silicon substrate 1; (c) selectively removing a prescribed portion of first thermal oxide film 3a to expose second active area 20; (d) forming second thermal oxide film 3b as a second insulating film on first and second active areas 10, 20; (e) performing an annealing process on first and second thermal oxide films 3a, 3b at or above a temperature for forming second thermal oxide film 3b; and (f) forming first gate electrode 6a on first active area 10 such that first and second thermal oxide films 3a, 3b undergoing the annealing process lie between first active area 10 and first gate electrode 6a, and forming second gate electrode 6b on second active area 20 such that second thermal oxide film 3b undergoing the annealing process lies between second active area 20 and second gate electrode 6b.

By manufacturing a semiconductor device with a dual gate insulating structure using the present manufacturing method, residual internal stress in silicon substrate 1, especially internal stress at the sidewalls of trench isolation film 2 in silicon substrate 1, can effectively be mitigated.

Conventionally, a further annealing process is not added prior to the step of forming first and second gate electrodes 6a, 6b, and a single annealing process for source/drain regions 8 after the step of forming first and second gate electrodes 6a, 6b is performed, intending to mitigate internal stress. However, since first and second thermal oxide films 3a, 3b serving as gate insulating films are sandwiched between first and second gate electrodes 6a, 6b and silicon substrate 1, the single annealing process cannot effectively mitigate internal stress. Additionally, as a low temperature process has been introduced in recent years, the single annealing process for source/drain regions 8 is least likely to produce a sufficient effect of mitigating stress. Consequently, internal stress often remains in silicon substrate 1, which results in a decrease in yield and reliability.

In contrast, according to the method of manufacturing a semiconductor device in this embodiment, a further step of an annealing process is added after the step of forming second thermal oxide film 3b and before the step of forming gate electrodes 6a, 6b. The internal stress in silicon substrate 1 generated by forming first thermal oxide film 3a can thus be mitigated, and a sufficient effect of mitigating stress can be produced. As a result, a crystal defect generated inside silicon substrate 1 can effectively be suppressed to decrease junction leakage and leakage current between a source and a drain. Crystal distortion caused by internal stress is also decreased to increase electron mobility.

Additionally, the annealing process for mitigating stress contributes to improvement in quality of first thermal oxide film 3a and second thermal oxide film 3b. Therefore, the additional annealing process can decrease gate leakage current and prevent dielectric breakdown of a field effect transistor.

By adopting the method of manufacturing a semiconductor device in the present embodiment as described above, a variety of electrical characteristics can be improved and a semiconductor device having a dual gate insulating film structure with increased yield and reliability can be provided.

When the method of manufacturing a semiconductor device as in the present embodiment is used, its effect is significantly exhibited especially in a semiconductor device where an active element area is designed to have a considerably small size. In a semiconductor device with an active area having a width of approximately 1 μm or less, for example, its electrical characteristic is significantly influenced by residual stress. Accordingly, an effect to improve an electrical characteristic obtained by the method of manufacturing a semiconductor device as in the present embodiment is remarkably heightened. There are various semiconductor devices with an active area designed to have a width of 1 μm or less, and an example of which is a high-density static random access memory (SRAM) or the like. For the SRAM, where individual gate regions are stressed in four directions, the above effect is significant.

When the method of manufacturing a semiconductor device in the embodiment described above is used, a step of forming second thermal oxide film 3b and a step of performing an annealing process to mitigate stress are more preferably done successively in a single apparatus for manufacturing a semiconductor device. Accordingly, manufacturing efficiency can be increased.

It is noted that though the present embodiment has been described illustrating a case where the present invention is applied to a semiconductor device having field effect transistors arranged in array, i.e., having a so-called gate array structure, an application of the present invention is not limited thereto. The present invention can, of course, be applied to a semiconductor device having a cell-based structure and the like.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device having field effect transistors with gate insulating films of different thicknesses comprising the steps of:
forming a trench isolation film at a main surface of a silicon substrate to form first and second active areas;
forming a first insulating film on said first and second active areas;
selectively removing a prescribed portion of said first insulating film to expose said second active area;
forming a second insulating film on said first and second active areas;
performing an annealing process on said first and second insulating films at or above a temperature for forming said second insulating film; and
forming a first gate electrode on said first active area such that said first and second insulating films undergoing the annealing process lie between said first active area and said first gate electrode, and forming a second gate electrode on said second active area such that said second insulating film undergoing the annealing process lies between said second active area and said second gate electrode.

2. The method of manufacturing a semiconductor device according to claim 1, wherein the temperature for forming said second insulating film is at most 1000° C.

3. The method of manufacturing a semiconductor device according to claim 1, wherein said first insulating film is formed through a thermal oxidization process in a wet atmosphere.

4. The method of manufacturing a semiconductor device according to claim 1, wherein said annealing process is performed with a rapid thermal anneal (RTA) method.

5. The method of manufacturing a semiconductor device according to claim 1, wherein said annealing process is performed in an atmosphere of inert gas.
